(19) United States
(12) Patent Application Publication
(10) Pub. No.: US 2003/0118939 A1
(43) Pub. Date: Jun. 26, 2003

(54) High speed negative working thermal printing plates

(75) Inventors: Heidi Munnelly, Windsor, CO (US); Paul West, Fort Collins, CO (US)

Correspondence Address: Paul W. Busse, Faegre & Benson LLP, 2200 Wells Fargo Center, 90 South Seventh Street, Minneapolis, MN, 55401-3901, US

(73) Assignee: KODAK POLYCHROME GRAPHICS, L.L.C., NORWALK, CT

(21) Appl. No.: 10/040,241

(22) Filed: Nov. 9, 2001

(51) Int. Cl. G03F 7/031; G03F 7/033; G03F 7/032; G03F 7/11; G03F 7/30; G03F 7/38; G03F 7/40; B41N 1/08; B41N 1/14

(52) U.S. Cl. 430/273.1; 430/944; 430/286.1; 430/910; 430/911; 430/915; 430/906; 430/923; 430/287.1; 430/302; 430/309; 430/18; 430/920; 430/922; 430/284.1; 430/926; 430/918; 430/917; 522/7; 522/15; 522/17; 522/16; 522/25; 522/27; 522/28; 522/30

(57) ABSTRACT

The present invention provides an IR-sensitive composition, which includes: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system, which includes: (a) at least one compound capable of absorbing IR radiation; (b) at least one compound capable of producing radicals; and (c) at least one carboxylic co-initiator, provided that the total acid number of the polymeric binder is 70 mg KOH/g or less. The present invention further provides a printing plate precursor, a process for preparing the printing plate and a method of producing an image.

### FIELD OF THE INVENTION

The present invention relates to an IR-sensitive composition that is suitable for use in the manufacture of negative-working printing plate precursors. More particularly, the present invention relates to a negative-working printing plate precursor that can be imagewise exposed to IR-radiation and developed to produce a lithographic printing plate.

### DESCRIPTION OF THE PRIOR ART

Improvement of the properties of radiation-sensitive compositions and parallel improvement of properties of the corresponding printing plate precursors can be addressed in two different ways. In the first approach, the performance and properties of the radiation-sensitive components in the compositions, such as, negative diazo resins or photoinitiators, can be improved. In the second approach, one can embark on a search for novel polymeric compounds, such as, binders, which can control the physical properties of the radiation-sensitive layer. The first approach is of particular importance in cases where the sensitivity of the printing plate precursors is to be adjusted to certain ranges of electromagnetic radiation, since the radiation-sensitivity as well as the shelf-life of the materials are strongly influenced by the nature of such initiator systems.

Recent developments in the field of printing plate precursors have occurred in the area of radiation-sensitive compositions that can be imagewise exposed by means of lasers or laser diodes. This type of exposure does not require the use of films as intermediate information carriers. This is possible because the lasers can be controlled directly by the use of computers.

High-performance lasers or laser diodes that are used in commercially available image-setters emit light in the wavelength ranges from about 800 nm to about 850, typically 830 nm and from about 1060 to about 1120 nm, typically 1064 nm. Accordingly, the printing plate precursors and the initiator systems contained in the printing plate precursors that are imagewise exposed by means of such image-setters, have to be sensitive in the near IR range. Such printing plate precursors can then be handled in daylight, which significantly facilitates their production and processing.

The radiation-sensitive compositions that are used in such printing plates can be either negative working or positive working. In the negative working printing plates, the exposed areas of the radiation-sensitive compositions are cured upon imagewise exposure. In the developing step only the unexposed areas are removed from the substrate. In the positive working printing plates, the exposed areas of the radiation-sensitive compositions dissolve faster in a given developing agent upon imagewise exposure than the non-exposed areas. This process is referred to as photosolubilization.

To produce a high number of copies in the positive systems, highly crosslinked polymers are generally needed. However, such products are also insoluble in the solvents or solvent mixtures commonly used for plate coating. Therefore, non-crosslinked or slightly crosslinked materials are used to promote solubility.

U.S. Pat. No. 5,491,046, European Patent Documents EP-A-0 672 544, EP-A-0 672 954 and EP-A-0 819 985 describe negative working plates that can be imagewise exposed with IR lasers. These negative working plates also require a preheating step, i.e., a post exposure heating step, within a very narrow temperature range, which produces only partial crosslinking of the image layer. In order to meet the highest requirements regarding the number of copies and to exhibit sufficient resistance to printing chemicals, an additional heating step, referred to as post development baking, is carried out. During the additional post development baking step, the image layer is further crosslinked.

All of the systems described above have the additional disadvantage of requiring relatively high exposure dose, i.e., ≧150 mJ/cm². For certain applications, such as, news printing, such doses are difficult to deliver while still providing the necessary number of exposed printing plates within a short period of time without inducing ablation.

U.S. Pat. No. 4,997,745 describes photosensitive compositions having a dye absorbing in the visible range and a trihalomethyl-s-triazine compound. However, these compositions do not have sufficient sensitivity in the IR-range. Moreover, they do not meet today's requirements of high photosensitivity and long shelf life.

U.S. Pat. No. 5,496,903 and German Patent Document DE-A-196 48 313 describe photosensitive compositions which include a dye absorbing in the IR range and borate or halogenated s-triazine co-initiators. Although these compositions have improved photosensitivity, the printing plates produced thereby do not meet the present-day long shelf life requirement. Thus, after only one month of storage at room temperature, the entire layer of the printing plate appears to have cured to such a degree that an image could no longer be created after exposure and developing of the plate.

Radiation-sensitive compositions which show both a high degree of radiation sensitivity and a sufficiently long shelf-life when used in the manufacture of printing plate precursors are presently known with visible light absorbing dyes, as those described in European Patent Document EP-A-0 730 201. However, printing plate precursors using such compositions have to be manufactured and processed under darkroom conditions. Further, such printing plate precursors cannot be imagewise exposed by means of the above-mentioned lasers or laser diodes. Thus, the fact that they cannot be processed in daylight particularly limits their applications.

International Patent Documents WO 99/46310 and WO 99/46301 describe method of preparing UV-curable, highly-branched, functionalized poly(methyl methacrylate) (PMMA) polymers and their use in coating formulations and photoresists. There is no disclosure or teaching in these documents of potential uses of these polymers in IR-imagable, negative-working lithographic plates.

European Patent Document EP 131,824 describes a photopolymerizable composition based on poly(methyl methacrylate) and multifunctional acrylic monomers for dry film resist and printed circuit board (PCB) applications. These coatings are imagewise exposed with ultraviolet or visible light. There are no teachings of imaging these compositions with wavelengths greater than 700 nm. Other photopolymerizable compositions with initiator systems are described in U.S. Pat. Nos. 5,756,258, 5,545,676 and 5,763,134, Japanese Patent Documents JP-A-11-038633 and JP-A-09-034110 and European Patent Document EP-B-0 522 175.

JP-A-159819, publication date Jun. 12, 2001, discloses a photopolymerizable composition having an alkaline soluble resin, an unsaturated compound and a photopolymerization initiator system, which is initiated with visible light. The initiator system is not infrared initiated.

European Patent Document EP 611,997 describes in a printing plate which the coating contains an acrylic polymer, average molecular weight: 150,000, pentaerythritol triacrylate, a triazine and a squarylium compound (IR dye) (see Example 1). The acid number or the specific composition of the polymethacrylate polymer is not disclosed.

U.S. Pat. No. 6,153,356 describes a composition, which includes an ethylenically unsaturated compound, near IR-absorbing cyanine dye with barbituric anion group or a thiobarbituric anion group, and photopolymerization initiator. The composition can contain a homopolymer or a copolymer of (meth)acrylic acid and a (meth)acrylate with polymer molecular weights from 10,000 to 500,000 g/mol. The polymer compositions with increasingly high acid numbers are preferred.

U.S. Pat. No. 5,368,990 describes a photopolymerizable composition, which includes an ethylenically unsaturated compound and a photopolymerization initiating composition having a dye and a diaryl iodonium salt as the photopolymerization initiator. The acrylic polymer used in examples 1 to 11 has an acid number of 75.

International Patent Document WO 00/48836 describes an IR-sensitive composition including an IR-absorber, free-radical generator system, and a polycarboxylic acid compound. This invention teaches the benefits of polymeric binders with high acid numbers in this type of system. The binders of this patent document have an acid number greater than 70 mg KOH/g. In addition, this invention utilizes a post-exposure heating step prior to developing, as shown in all the examples.

It is therefore an object of the present invention to provide IR-sensitive compositions which allow the manufacture of negative printing plate precursors having a long shelf-life, providing a continuously high number of copies and a high degree of resistance to developing chemicals, and which are additionally characterized by high IR sensitivity, resolving power, processability in daylight, fast cure rate and low energy requirements.

Another object underlying this invention is the use of such IR-sensitive compositions to prepare negative working printing plate precursors, which do not required a post-exposure bake and have excellent latent image stability.

These objects are achieved by a fast curing IR-sensitive composition according to the present invention that has a low energy requirement.

### SUMMARY OF THE INVENTION

The present invention provides an IR-sensitive composition. The IR-sensitive composition includes:

a polymeric binder; and

a free radical polymerizable system consisting of: at least one component selected from unsaturated free radical polymerizable monomers, oligomers which are free radical polymerizable and polymers containing C═C bonds in the backbone and/or in the side chain groups; and an initiator system including: (a) at least one compound capable of absorbing IR radiation; (b) at least one compound capable of producing radicals; and (c) at least one carboxylic acid represented by the formula:

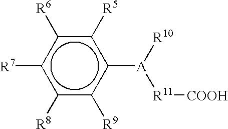

wherein each of R⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵ and R⁶, R⁶ and R⁷, R⁷ and R⁸, or R⁸ and R⁹ together optionally form an aromatic or aliphatic ring; wherein R¹⁰ is selected from the group consisting of: hydrogen, alkyl, aryl, hydroxyalkyl, carboxyalkyl, acyl, alkoxycarbonyl, alkylsulfonyl and alkylsulfonate; or R¹⁰ and its bond together optionally form an electron pair; or R⁹and R¹¹ together optionally form a ring; wherein R¹¹ is an alkylene group of C₁-C₆ carbon atoms; and wherein R¹⁰ and R¹¹ together optionally form an aliphatic ring; wherein A is a heteroatom selected from the group consisting of: N, O and S; with the proviso that the total acid number of the polymeric binder is 70 mg KOH/g or less.

More particularly, the IR-sensitive composition includes: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system including: (a) at least one compound capable of absorbing IR radiation; (b) at least one compound capable of producing radicals; and (c) at least one polycarboxylic acid having an aromatic moiety substituted with a heteroatom selected from N, O and S and further having at least two carboxyl groups wherein at least one of the carboxyl groups is bonded to the heteroatom via a methylene group; with the proviso that the total acid number of the polymeric binder is 70 mg KOH/g or less.

The present invention further provides a printing plate precursor, which includes:

a substrate; and

coated on the substrate an IR-sensitive composition including: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system including: (a) at least one compound capable of absorbing IR radiation; (b) at least one compound capable of producing radicals; and (c) at least one carboxylic acid represented by the formula:

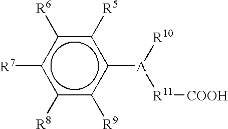

wherein each of R⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵ and R⁶, R⁶ and R⁷, R⁷ and R⁸, or R⁸ and R⁹ together optionally form an aromatic or aliphatic ring; wherein R¹⁰ is selected from the group consisting of: hydrogen, alkyl, aryl, hydroxyalkyl, carboxyalkyl, acyl, alkoxycarbonyl, alkylsulfonyl and alkylsulfonate; or R¹⁰ and its bond together optionally form an electron pair; or R⁹ and R¹¹ together optionally form a ring; wherein R¹¹ is an alkylene group of C₁-C₆ carbon atoms; and wherein R¹⁰ and R¹¹ together optionally form an aliphatic ring; wherein A is a heteroatom selected from the group consisting of: N, O and S; with the proviso that the total acid number of the polymeric binder is 70 mg KOH/g or less.

The present invention still further provides a process for preparing a printing plate, including:

imagewise exposing a printing plate precursor to IR radiation, the printing plate precursor including: a substrate; and coated on the substrate an IR-sensitive composition including: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system including: (a) at least one compound capable of absorbing IR radiation; (b) at least one compound capable of producing radicals; and

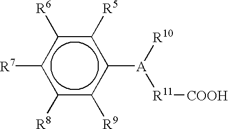

wherein each of R⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵ and R⁶, R⁶ and R⁷, R⁷ and R⁸, or R⁸ and R⁹ together optionally form an aromatic or aliphatic ring; wherein R¹⁰ is selected from the group consisting of: hydrogen, alkyl, aryl, hydroxyalkyl, carboxyalkyl, acyl, alkoxycarbonyl, alkylsulfonyl and alkylsulfonate; or R¹⁰ and its bond together optionally form an electron pair; or R⁹ and R¹¹ together optionally form a ring; wherein R¹¹ is an alkylene group of C₁-C₆ carbon atoms; and wherein R¹⁰ and R¹¹ together optionally form an aliphatic ring; wherein A is a heteroatom selected from the group consisting of: N, O and S; with the proviso that the total acid number of the polymeric binder is 70 mg KOH/g or less; and thereafter

developing with a developer solution to produce the printing plate.

The present invention also provides a method for producing an image, including:

coating an optionally pretreated substrate with an IR-sensitive composition including: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system including: (a) at least one compound capable of absorbing IR radiation; (b) at least one compound capable of producing radicals; and (c) at least one carboxylic acid represented by the formula:

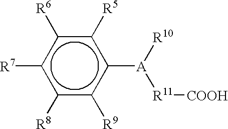

wherein each of R⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵ and R⁶, R⁶ and R⁷, R⁷ and R⁸, or R⁸ and R⁹ together optionally form an aromatic or aliphatic ring; wherein R¹ is selected from the group consisting of: hydrogen, alkyl, aryl, hydroxyalkyl, carboxyalkyl, acyl, alkoxycarbonyl, alkylsulfonyl and alkylsulfonate; or R¹⁰ and its bond together optionally form an electron pair; or R⁹ and R¹¹ together optionally form a ring; wherein R¹¹ is an alkylene group of C₁-C₆ carbon atoms; and wherein R¹⁰ and R¹¹ together optionally form an aliphatic ring; wherein A is a heteroatom selected from the group consisting of: N, O and S; with the proviso that the total acid number of the polymeric binder is 70 mg KOH/g or less to produce a printing plate precursor;

imagewise exposing the printing plate precursor to IR radiation to produce an imagewise exposed printing plate precursor; and

developing the precursor with an aqueous developer to obtain a printing plate having thereon a printable lithographic image.

The use of special processors with built in heaters is required for production of plates that require a preheating step (post exposure heating step). Such processors typically have a larger footprint and consume much more energy for operation than the counterparts that are without preheating ovens for post exposure heating. The IR-sensitivity of compositions according to the present invention, which include poly(methyl methacrylate)-based binders having 70 mg KOH/g or lower acid numbers, are increased by about 50-60 mJ/cm² over those described in WO 00/48836 with IR-sensitivities of about 120 mJ/cm² for optimal resolution and on-press performance. Thus, the printing plates prepared according to the present invention require only about 60 mJ/cm² for optimal resolution and on-press performance.

Furthermore, in the present invention, improvement in the IR-sensitivity is achieved without post-exposure bake. Thus, with increased IR-sensitivity and without a pre-development heating, i.e., post-exposure bake requirement, the number of plates that can be imaged and processed within a period of time is greatly increased. High power imaging lasers are therefore not required for high speed imaging of the plates according to the present invention. With the elimination of the preheating step, establishing proper exposure energies and image quality are also more reproducible.

Latent image stability is also a common problem associated with high speed, photopolymer plates. Typically, depending on the relative humidity, latent images begin fading by about 20 minutes. With the elimination of the post-exposure bake, the latent image stability of the plates described in this Invention has improved by at least three-orders of magnitude (stable for months or more) over those described in WO 00/48836. As a result, the present invention saves time and energy costs to the end user. In addition, the plates according to the present invention are not expected to be sensitive to high humidity conditions.

### DETAILED DESCRIPTION OF THE INVENTION

The present invention describes high-speed, negative-working, IR-sensitive lithographic plates for commercial printing for which the need for a post-exposure bake requirement has been eliminated and the IR-sensitivity has been improved by greater than 50% over currently available photopolymerizable, negative-working, thermal preheat plates.

The terms “preheat” or “preheating,” such as, “preheating step” or “preheating oven,” in the context of the present invention refer to “post exposure” but pre-development heating. Thus, a no preheat printing plate is a plate that does not require a heating step between the exposure and the development steps.

Accordingly, the present invention provides an IR-sensitive composition including a polymeric binder, which preferably is an acrylic polymer, and a free radical polymerizable system. The total acid number of the polymeric binder is 70 mg KOH/g or less.

Basically all polymers or polymer mixtures known in the art can be used as polymeric binders. Suitable classes of such polymers include, for example, acrylic and methacrylic polymers and copolymers, such as, polymers and copolymers derived from acrylate and methacrylate esters and cellulose polymers, such as, cellulose acetate, cellulose propionate, cellulose butyrate, and cellulose polymers having mixed acyl groups, such as, cellulose acetate propionate. Preferably, the polymers have a weight-average molecular weight in the range of 10,000 to 1,000,000 (determined by GPC).

To achieve good image integrity without a post-exposure bake, it is preferred that the polymer used has an acid number of 70 mg KOH/g or less. When polymer mixtures are used, the arithmetic average of the individual acid numbers must be 70 mg KOH/g or less. Preferably, the total acid number of the polymeric binder is 50 mg KOH/g or less. More preferably, the total acid number of the polymeric binder is 30 mg KOH/g or less. Especially preferred are polymers with total acid number 10 mg KOH/g or less, including zero. Most preferred polymers are those having a total acid number equal to zero.

Preferably, these polymers are polymers and copolymers derived from acrylate and methacrylate esters, such as, for example, methyl, ethyl, butyl and benzyl esters of acrylic and methacrylic acids. Especially preferred is poly(methyl methacrylate). The composition can further include additional polymers and copolymers. However, in all cases, the total acid number must remain 70 mg KOH/g or less.

All molecular weight characterizations are done by gel permeation chromatography (GPC) and the total acid number is determined by summing the weight percents of the original polymer acid numbers, which were determined by titration.

The molecular weight of the polymers derived from acrylate and methacrylate esters can be from 1,000 to 1,000,000 g/mol. Preferably, the molecular weight of the polymers is about 100,000 g/mol, more preferably, the molecular weight of the polymers is about 70,000 g/mol. Especially preferred, are polymers with molecular weights about 40,000 g/mol. Preferably the polymers can be linear or branched, with polydispersities of 1 to 5.

The content of the polymeric binder in the IR-sensitive composition accounts for 20 to 80 wt %, preferably 30 to 60 wt %, more preferably 35 to 45 wt %, of the total solids content of the IR-sensitive composition.

The free radical polymerizable system has one or more of: unsaturated free radical polymerizable monomers, oligomers which are free radical polymerizable and polymers containing C═C bonds in the backbone and/or in the side chain groups and an initiator system.

The initiator system has (a) at least one compound capable of absorbing IR radiation; (b) at least one compound capable of producing radicals; and (c) at least one mono or polycarboxylic acid represented by the formula:

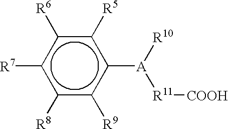

wherein each of R ⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵ and R⁶, R⁶ and R⁷, R⁷ and R⁸, or R⁸ and R⁹ together optionally form an aromatic or aliphatic ring; wherein R¹⁰ is selected from the group consisting of: hydrogen, alkyl, aryl, hydroxyalkyl, carboxyalkyl, acyl, alkoxycarbonyl, alkylsulfonyl and alkylsulfonate; wherein R¹⁰ and its bond together optionally form an electron pair; or R⁹ and R¹¹ together optionally form a ring; wherein R¹¹ is an alkylene group of C₁-C₆ carbon atoms; and wherein R¹⁰ and R¹¹ together optionally form an aliphatic ring; wherein A is a heteroatom selected from the group consisting of: N, O and S.

The polycarboxylic acid preferably has an aromatic moiety substituted with a heteroatom selected from N, O and S and further having at least two carboxyl groups wherein at least one of the carboxyl groups is bonded to the heteroatom via a methylene group.

Useful infrared absorbing compounds typically have a maximum absorption wavelength in some part of the electromagnetic spectrum greater than about 750 nm; more particularly, their maximum absorption wavelength is in the range from 780 to 1100 nm.

Preferably, component (a) includes at least one compound selected from triarylamine dyes, thiazolium dyes, indolium dyes, oxazolium dyes, cyanine dyes, polyaniline dyes, polypyrrole dyes, polythiophene dyes, leuco dyes and phthalocyanine pigments and dyes.

It is more preferred that component (a) includes a cyanine dye of the formula (A)

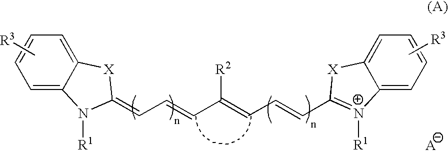

wherein each X can independently be S, O, NR or C(alkyl)₂;

each R¹ can independently be an alkyl, an alkylsulfonate or an alkylammonium group;

R² can be hydrogen, halogen, SR, SO₂R, OR or NR₂;

each R³ can independently be a hydrogen, an alkyl group, COOR, OR, SR, SO₃⁻, NR₂, a halogen, and an optionally substituted benzofused ring;

A⁻ represents an anion;

--- represents an optional five- or six-membered carbocyclic ring;

wherein each R can independently be hydrogen, an alkyl and an aryl group; and

wherein each n can independently be 0, 1, 2 or 3.

If R¹ is an alkylsulfonate group, A⁻ can be absent due to the formation of an inner salt and an alkali metal cation would be necessary as a counterion. If R¹ is an alkylammonium group, a second anion would be necessary as counterion. The second anion can be the same as A⁻ or it can be a different anion.

Compound (b) preferably is selected from polyhaloalkyl substituted compounds and azinium compounds.

In the present free radical polymerizable system the radical is formed between component (a) and component (b) and the carboxylic acid. In order to achieve a high degree of radiation sensitivity, the presence of all three components is indispensable. It was found that completely radiation-insensitive compositions were obtained when component (b) was missing.

The polycarboxylic acid is necessary to obtain the required thermal speed without sacrificing stability. If the polycarboxylic acid is replaced for example by ammonium borates, the radiation sensitivity can be slightly decreased and the thermal stability of such compositions can be insufficient.

Suitable unsaturated free radical polymerizable monomers or oligomers include, for example, acrylic or methacrylic acid derivatives with one or more unsaturated groups, preferably esters of acrylic or methacrylic acid in the form of monomers, oligomers or prepolymers. They can be present in solid or liquid form, with solid and highly viscous forms being preferred.

The compounds suitable as monomers include, for example, trimethylolpropane triacrylate and methacrylate, pentaerythritol triacrylate and methacrylate, dipentaerythritol monohydroxy pentaacrylate and methacrylate, dipentaerythritol hexaacrylate and methacrylate, pentaerythritol tetraacrylate and methacrylate, ditrimethylolpropane tetraacrylate and methacrylate, diethyleneglycol diacrylate and methacrylate, triethyleneglycol diacrylate and methacrylate or tetraethyleneglycol diacrylate and methacrylate.

Suitable oligomers and/or prepolymers include urethane acrylates and methacrylates, such as, the reaction product of Desmodur N-100, hydroxyethyl acrylate and pentaerythritol triacrylate; epoxide acrylates and methacrylates; polyester acrylates and methacrylates; polyether acrylates and methacrylates; and unsaturated polyester resins.

In addition to monomers and oligomers, polymers having C═C bonds in the backbone and/or in the side chains can also be used. Examples include: reaction products of maleic anhydride-olefin-copolymers and hydroxyalkyl(meth)acrylates, polyesters containing an allyl alcohol group, reaction products of polymeric polyalcohols and isocyanatoalkyl (meth)acrylates, unsaturated polyesters, (meth)acrylate terminated polystyrenes, poly(meth)acrylics and polyethers.

The weight ratio of the free radical polymerizable monomers or oligomers is from about 25 wt % to about 75 wt %, preferably from about 35 wt % to about 60 wt %, more preferably from about 45 wt % to about 55 wt %, of the total solids content of the IR-sensitive composition.

The initiator system of the present invention includes as an essential component a compound capable of absorbing IR radiation. This IR absorber is preferably selected from triarylamine dyes, thiazolium dyes, indolium dyes, oxazolium dyes, cyanine dyes, polyaniline dyes, polypyrrole dyes, polythiophene dyes, and phthalocyanine pigments and dyes. More preferred are IR dyes of the formula (A):

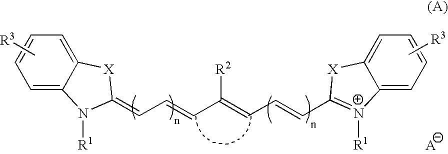

wherein each X can independently be S, O, NR or C(alkyl)₂;

each R¹ can independently be an alkyl, an alkylsulfonate or an alkylammonium group;

R² can be hydrogen, halogen, SR, S0₂R, OR or NR₂;

each R³ can independently be a hydrogen, an alkyl group, COOR, OR, SR, SO₃⁻, NR₂, a halogen, or an optionally substituted benzofused ring;

A⁻ represents an anion;

--- represents an optional five- or six-membered carbocyclic ring;

wherein each R can independently be hydrogen, an alkyl or an aryl group; and

wherein each n can independently be 0, 1, 2 and 3.

These dyes absorb in the range of 750 to 1100 nm. Dyes of the formula (A), which absorb in the range of 780 to 860 nm, are preferred.

Particularly preferred IR dyes of the formula (A) include compounds in which:

X is preferably a C(alkyl)₂ group;

R¹ is preferably an alkyl group with 1 to 4 carbon atoms;

R² is preferably SR;

R³ is preferably hydrogen;

R is preferably an alkyl or aryl group: especially preferred is a phenyl group;

--- (i.e., a broken line), preferably represents the rest of a ring with 5 or 6 carbon atoms; and

counterion A⁻ is preferably a chloride ion or a tosylate anion.

Especially preferred include IR dyes that are symmetrical, such as the symmetrical dyes represented by formula (A). Examples of such especially preferred dyes include:

2-[2-[2-phenylsulfonyl-3-[2-(1,3-dihydro-1,3,3-trimethyl-2H-indol-2-ylidene)-ethylidene]-1-cyclohexen-1-yl]-ethenyl]-1,3,3-trimethyl-3H-indoliumchloride;

2-[2-[2-thiophenyl-3-[2-(1,3-dihydro-1,3,3-trimethyl-2H-indol-2-ylidene)-ethylidene]-1-cyclohexen-1-yl]-ethenyl]-1,3,3-trimethyl-3H-indoliumchloride;

2-[2-[2-thiophenyl-3-[2-(1,3-dihydro-1,3,3-trimethyl-2H-indol-2-ylidene)-ethylidene]-1-cyclopenten-1-yl]-ethenyl]-1,3,3-trimethyl-3H-indoliumtosylate;

2-[2-[2-chloro-3-[2-ethyl-(3H-benzthiazole-2-ylidene)-ethylidene]-1-1cyclohexen-1-yl]-ethenyl]-3-ethyl-benzthiazolium-tosylate; and

2-[2-[2-chloro-3-[2-(1,3-dihydro-1,3,3-trimethyl-2H-indol-2-ylidene)-ethylidene]-1-cyclohexen-1-yl]-ethenyl]-1,3,3-trimethyl-3H-indoliumtosylate.

Additional IR absorbers that are useful in the compositions of the present invention include the following compounds:

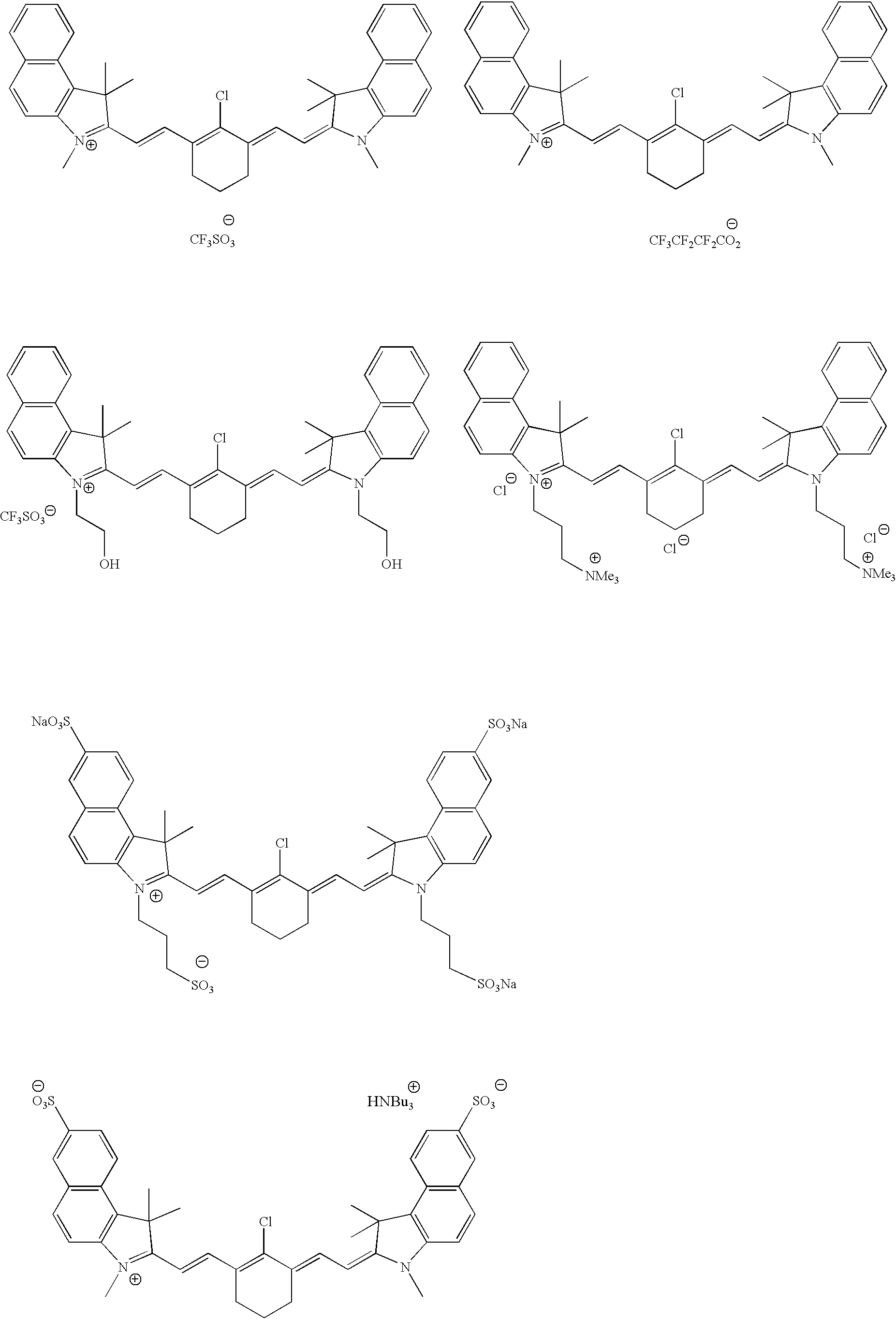

The IR absorber (a) is preferably present in the IR-sensitive composition in an amount of from about 0.05 wt % to about 20 wt %, preferably from about 0.5 to 8 wt %, and more preferably from about 1.0 to 3 wt %, based on the total solids content of the IR-sensitive composition.

Another essential component of the initiator system is the compound capable of producing radicals (b). Preferably this compound is selected from polyhaloalkyl substituted compounds and azinium compounds. Especially preferred are polyhaloalkyl-substituted compounds. These are compounds that contain either one poly halogenated or several monohalogenated alkyl substituents. The halogenated alkyl group preferably has 1 to 3 carbon atoms. Especially preferred is a halogenated methyl group.

The absorption properties of the polyhaloalkyl-substituted compound fundamentally determine the daylight stability of the IR-sensitive composition. Compounds having a UVNIS absorption maximum of >330 nm result in compositions which can no longer be completely developed after the printing plate has been kept in daylight for 6 to 8 minutes and then been reheated. Such compositions could be imagewise exposed not only with IR but also with UV radiation. If a high degree of daylight stability is desired, polyhaloalkyl-substituted compounds are preferred which do not have a UVNIS absorption maximum at >330 nm.

The azinium compounds include an azinium nucleus, such as a pyridinium, diazinium, or triazinium nucleus. The azinium nucleus can include one or more aromatic rings, typically carbocyclic aromatic rings, fused with an azinium ring. In other words, the azinium nuclei include quinolinium, isoquinolinium, benzodiazinium, and naphthodiazonium nuclei. To achieve the highest attainable activation efficiencies per unit of weight it is preferred to employ monocyclic azinium nuclei.

A quaternizing substituent of a nitrogen atom in the azinium ring is capable of being released as a free radical upon electron transfer from the photosensitizer to the azinium compound. In one preferred form the quaternizing substituent is an oxy substituent. The oxy substituent (—O—R), which quaternizes a ring nitrogen atom of the azinium nucleus can be selected from among a variety of synthetically convenient oxy substituents. The moiety R can, for example, be an alkyl radical, which can be substituted; for example aralkyl and sulfoalkyl groups are contemplated. Most preferred oxy substituents (—O—R) contain 1 or 2 carbon atoms.

Examples of especially suitable compounds (b) for the compositions of the present invention include:

N-methoxy-4-phenylpyridinium tetrafluoroborate tribromomethylphenylsulfone;

1,2,3,4-tetrabromo-n-butane;

2-(4-methoxyphenyl)-4,6-bis(trich loromethyl)-s-triazine;

2-(4-chlorophenyl)-4,6-bis(trichloromethyl)-s-triazine;

2-phenyl-4,6-bis(trichloromethyl)-s-triazine;

2,4,6-tri-(trichloromethyl)-s-triazine;

2,4,6-tri-(tribromomethyl)-s-triazine;

2-hydroxytetradecyloxyphenyl phenyliodonium hexafluoroantimonate; and

2-methoxy-4-phenylaminobenzenediazonium hexafluorophosphate.

Further, the following compounds are useful as initiators (b) in the compositions of the present invention:

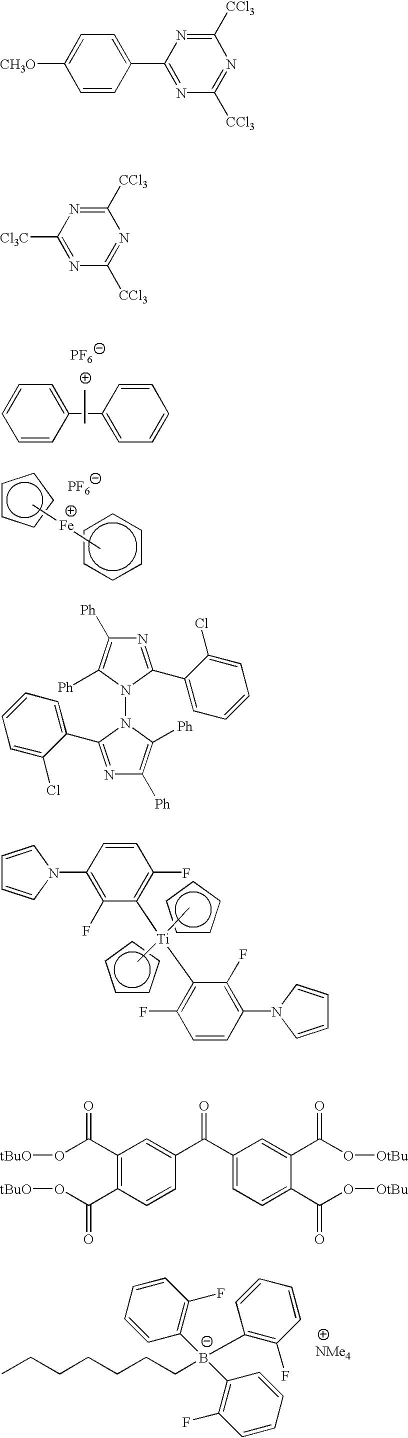

Compound (b) is preferably present in the IR-sensitive composition in an amount of from 2 to 15 wt %, based on the total solids content of the IR-sensitive composition; especially preferred is an amount of from 4 to 7 wt %.

The carboxylic acid, which is compound (c), can be any carboxylic acid that is capable of serving in the initiator system as a co-initiator with the compound capable of producing radicals. Preferably, the carboxylic acid has an aromatic moiety substituted with a heteroatom selected from N, O and S. Preferably, the carboxylic acid includes at least two carboxyl groups (a polycarboxylic acid) at least one of which is bonded to the heteroatom via a methylene group. While polycarboxylic acids are preferred, mono carboxylic, i.e., having one carboxylic acid group, are also suitable for use in the IR-sensitive compositions of the present invention. The preferred examples of the monocarboxylic acids include N-aryl-α-amino carboxylic acids, such as, PhNHCH₂COOH and preferred examples of the polycarboxylic acids include N-phenyliminodiacetic acid. Further examples of preferred carboxylic acids include:

(p-acetamidophenylimino)diacetic acid;

3-(bis(carboxymethyl)amino)benzoic acid;

4-(bis(carboxymethyl)amino)benzoic acid;

2-((carboxymethyl)phenylamino)benzoic acid;

2-((carboxymethyl)phenylamino)-5-methoxybenzoic acid;

3-(bis(carboxymethyl)amino-2-naphthalenecarboxylic acid;

N-(4-aminophenyl)-N-(carboxymethyl)glycine;

N,N′-1,3-phenylenebisglycine;

N, N′-1,3-phenylenebis(N-(carboxymethyl))glycine;

N, N′-1,2-phenylenebis(N-(carboxymethyl))glycine;

N-(carboxymethyl)-N-(4-methoxyphenyl)glycine;

N-(carboxymethyl)-N-(3-methoxyphenyl)glycine;

N-(carboxymethyl)-N-(3-hydroxyphenyl)glycine;

N-(carboxymethyl)-N-(3-chlorophenyl)glycine;

N-(carboxymethyl)-N-(4-bromophenyl)glycine;

N-(carboxymethyl)-N-(4-chlorophenyl)glycine;

N-(carboxymethyl)-N-(2-chlorophenyi)glycine;

N-(carboxymethyl)-N-(4-ethylphenyl)g lycine;

N-(carboxymethyl)-N-(2,3-dimethylphenyl)glycine;

N-(carboxymethyl)-N-(3,4-dimethylphenyl)g lycine;

N-(carboxymethyl)-N-(3,5-dimethylphenyl)glycine;

N-(carboxymethyl)-N-(2,4-dimethylphenyl)glycine;

N-(carboxymethyl)-N-(2,6-dimethylphenyl)glycine;

N-(carboxymethyl)-N-(4-formylphenyl)glycine;

N-(carhoxymethyl)-N-ethylanthranilic acid;

N-(carboxymethyl)-N-propylanthranilic acid;

5-bromo-N-(carboxymethyl)anthranilic acid;

N-(2-carboxyphenyl)glycine;

o-dianisidine-N,N,N′,N′-tetraacetic acid;

N, N′-(1,2-ethanediylbis(oxy-2, 1-phenylene))bis(N-(carboxymethyl)glycine);

4-carboxyphenoxyacetic acid;

catechol-O,O′-diacetic acid;

4-methylcatechol-O,O′-diacetic acid;

resorcinol-O,O′-diacetic acid;

hydroquinone-O,O′-diacetic acid;

α-carboxy-o-anisic acid;

4,4′-isopropylydenediphenoxyacetic acid;

2,2′-(dibenzofuran-2, 8-d iyldioxy)diacetic acid;

2-(carboxymethylthio)benzoic acid;

5-amino-2-(carboxymethylthio)benzoic acid; and

3-((carboxymethyl)thio)-2-naphtalenecarboxylic acid.

The preferred polycarboxylic acids include N-arylpolycarboxylic acids, particularly those having the following formula (B):

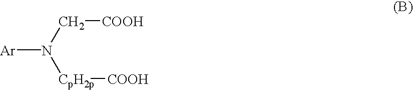

wherein Ar is a mono-, poly- or unsubstituted aryl group and p is an integer from 1 to 5, and those of the formula (C):

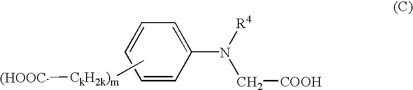

wherein R⁴ represents hydrogen or a C₁-C₆ alkyl group and k and m each represent an integer from 1 to 5.

Possible substituents of the aryl group in formula (B) are C₁-C₃ alkyl groups, C₁-C₃ alkoxy groups, C₁-C₃ thioalkyl groups and halogen atoms. The aryl group can have 1 to 3 identical or different substituents and preferably, p is 1, and preferably, Ar represents a phenyl group. In formula (C), m is preferably 1 and R⁴ preferably represents hydrogen. The most preferred polycarboxylic acid is N-phenyliminodiacetic acid.

The mono or polycarboxylic acid is preferably present in the IR-sensitive composition in an amount of from 1 to 10 wt %, especially preferred 1.5 to 3 wt %, based on the total solids content of the IR-sensitive composition.

The IR-sensitive composition can further include dyes for improving the contrast of the image. Suitable dyes are those that dissolve well in the solvent or solvent mixture used for coating or are easily introduced in the disperse form of a pigment. Suitable contrast dyes include rhodamine dyes, triarylmethane dyes, methyl violet, anthroquinone pigments and phthalocyanine dyes and/or pigments. The dyes are preferably present in the IR-sensitive composition in an amount from 1 to 15 wt %, preferably in an amount from 2 to 7 wt %.

The IR-sensitive compositions of the present invention can further include a plasticizer. Suitable plasticizers include dibutyl phthalate, triaryl phosphate and dioctyl phthalate. If a plasticizers is used, it is preferably present in an amount in the range of 0.25 to 2 wt- %.

The IR-sensitive compositions of the present invention are suitable for use in the manufacture of printing plate precursors. They can be used in recording compositions for creating images on suitable substrates and receiving sheets, for creating reliefs that can serve as printing plates, screens and the like. In addition, they can be used in radiation curable varnishes for surface protection and in formulations of radiation-curable printing inks. For the manufacture of offset printing plate precursors, any conventional substrate can be used. Preferably, the support should be strong, stable and flexible. It should also resist dimensional change under conditions of use so that color records will register in a full color image. It can be any self-supporting materials, including polymeric films, such as, polyethylene terephthalate film, ceramics, metals, stiff papers or a lamination of any of these materials. Examples of such metal supports include aluminum, zinc, titanium and alloys thereof. The use of an aluminum substrate is especially preferred. Preferably, the surface of the aluminum substrate is first roughened. The roughening can be carried out by brushing in a dry state or by brushing with an abrasive suspension. It can be also carried out electrochemically, e.g., in an hydrochloric acid electrolyte. The roughened substrate plates, which can optionally be anodically oxidized in sulfuric or phosphoric acid, are then subjected to a hydrophilizing after-treatment, preferably in an aqueous solution of polyvinylphosphonic acid or phosphoric acid. Preferably, the substrate is a pretreated, hydrophilic substrate, such as, aluminum or polyester. The details of the above-mentioned substrate pretreatment are well known to the person skilled in the art. The dried substrate is then coated with the IR-sensitive composition of the present invention using an organic solvent or solvent mixtures to produce a coated layer preferably having a dry weight of from about 0.5 to about 4.0 g/m², more preferably from about 0.8 to about 3.0 g/m², and most preferably from about 1.0 to about 2.5 g/m².

An oxygen-impermeable layer can be applied on top of the IR-sensitive layer by methods known in the art. In the context of the present invention the term “oxygen-impermeable layer” includes layers that have low permeability to oxygen. The oxygen-impermeable layer can include polyvinyl alcohol, a polyvinyl alcohol/polyvinyl acetate copolymer, polyvinyl pyrrolidone, polyvinyl pyrrolidone/polyvinyl acetate copolymer, polyvinyl methyl ether, polyacrylic acid and gelatin. The dry layer weight of the oxygen impermeable layer is preferably 0.1 to 4 g/m2, more preferably 0.3 to 2 g/m². This overcoat is not only useful as oxygen barrier but also it protects the plate against ablation during exposure to IR radiation.

The printing plate precursors obtained in this manner are imagewise exposed using, for example, semiconductor lasers or laser diodes that emit in the range of from about 800 nm to about 1,100 nm. Such a laser beam can be digitally controlled via a computer, i.e., it can be turned on or off so that an imagewise exposure of the plates can be effected via stored digitalized information in the computer. Accordingly, the IR sensitive compositions of the present invention are suitable for producing what is referred to as computer-to-plate (ctp) printing plates. Alternatively, the thermally imagable element may be imaged using an apparatus containing a thermal printing head. An imaging apparatus suitable for use in conjunction with thermally imagable elements includes at least one thermal head but would usually include a thermal head array, such as, the TDK Model No. LV5416, which can be used in thermal fax machines and sublimation printers, and the GS618-400 thermal plotter (Oyo Instruments, Houston, Tex., USA). Suitable commercially available imaging devices include imagesetters, such as, CREO TRENDSETTERS (CREOSCITEX, British Columbia, Canada) and the GERBER CRESCENT 42T.

After the printing plate precursor is imagewise exposed, it can be optionally heated to a temperature from about 85° C. to about 135° C. for a brief period of time in order to effect complete curing of the exposed areas. Depending on the temperature applied, this would take only about 20 to about 100 seconds. Then the plates are developed in the aqueous developing compositions by methods known to those skilled in the art, such as those described in U.S. Pat. No. 5,035,982. Thereafter, the developed plates can be treated with a preservative. The preservatives are aqueous solutions of hydrophilic polymers, wefting agents and other additives.

The following examples serve to provide a detailed demonstration of the negative-working lithographic plates, which have improved IR-sensitivity and improved latent image stability but have no post-exposure baking requirement.

### EXAMPLE 1

A base coat solution containing the following components was prepared as shown in Table 1.

TABLE 1
Example 1 Base Coat Formulation

| Parts by Weight | Component |
|---|---|
| 3.55 | Urethane acrylate prepared by reacting 1-methyl-2,4- |
| | bis-isocyanate benzene (Desmodur N100 ®; Bayer) |
| | with hydroxyethyl acrylate and pentaerythritol |
| | triacrylate |
| 0.74 | Sartomer 355 (multi-functional acrylic monomer; |
| | Sartomer Co., Inc., ditrimethylolpropane tetraacrylate) |
| 3.24 | Elvacite 4026 (highly-branched poly(methyl |
| | methacrylate) with an acid number of 0, MW 32.5 K, |
| | MW/Mn = 4.3; from Ineos Acrylics, Inc., Cordova, |
| | TN) |
| 0.40 | (2-(4-methoxyphenyl)-4,6-bis(trichloromethyl)-2- |
| | triazine |
| 0.22 | N-phenyliminodiacetic acid |
| 0.08 | 2-[2-[2-thiophenyl-3-[2-(1,3-dihydro-1,3,3-trimethyl- |
| | 2H-indol-2-ylidene)-ethylidene]-1-cyclohexen-1-yl]- |
| | ethenyl]-1,3,3-trimethyl-3H-indoliumchloride |
| 0.10 | Crystal Violet |
| 0.02 | Byk307 (modified polysiloxane; Byk Chemie) |
| 13.75 | Methyl ethyl ketone |
| 22.91 | Toluene |
| 54.99 | 1-methoxy-2-propanol |

The above solution was coated on electrochemically grained and anodized aluminum which had a polyvinylphosphonic acid post-treatment with a wire-wound rod to yield a dry coating weight of 2 g/M². The plates were dried at about 94° C. for 60 sec residence time in a Ranar conveyor oven. The overcoat solution was prepared from 5.26 parts of Airvol 203, 0.93 parts polyvinylimidazole, 3.94 parts isopropanol, and 89.87 parts water. After applying the overcoat in a similar manner as the base coat, the plates were dried at 94° C. for 90 seconds residence time in a Ranar conveyor oven. The overcoat also had a dry coating weight of 2 g/m². These plates were imaged on a Creo Trendsefter 3244× at 2 W and 35 to 250 rpm. This exposure series ranged from 20 to 150 mJ/cm². The minimum exposure energy necessary to achieve maximum processed density was about 26 mJ/cm². Plates were processed without a post-exposure bake with a developer solution as described in Table 2.

TABLE 2
Example 1 Developer Formulation

| Component | Parts by Weight |
|---|---|
| Water | 83.58 |
| Sodium Xylene Sulfonate (40%) | 3.83 |
| Sodium Toluene Sulfonate (40%) | 1.73 |
| Benzyl Alcohol | 3.41 |
| Poly(vinyl Alcohol) 205 (10%) | 4.16 |
| Diethanolamine (85%) | 0.36 |
| Sodium Dodecylbenzene Sulfonate | 0.27 |
| Triton H-66 (50%) (from Rohm & Haas) | 2.66 |

Plates mounted on a Miehle sheet-fed press produced about 5,000 excellent reproductions under accelerated wearing conditions using black ink containing 1.5 wt % calcium carbonate. The number of impressions increased to about 50,000 under accelerated wearing conditions by UV-curing the plates prior to mounting on press. UV-curing was accomplished by flood exposing the plates on an Olec vacuum frame (5 kW bulb) with 22 units.

### EXAMPLES 2, 3 and 4

The base coat formulations for examples 2, 3 and 4 were prepared as described in Example 1 except that in place of the Elvacite 4026, poly(methyl methacrylate) polymers (both from Aldrich) with a MW of either 10 K (Example 2) or 30 K (Example 3) or (methyl methacrylate)/methacrylic acid copolymer (from Ineos Acrylics, Inc.) with a MW about 35K (Example 4) were substituted. Each of these polymers had polydispersities from 1-1.8 and an acid number of 0 (Examples 2 & 3) and 9 (Example 4). The base coat was applied and the overcoat prepared and applied as described in Example 1. Plates were imaged and processed as described in Example 1. The minimum exposure energies necessary to achieve maximum processed density were about 35 mJ/cm², about 26 mJ/cm² and about 40 mJ/cm² for Examples 2, 3 and 4, respectively.

### Comparative Example 1

In this example, the Elvacite 4026 in Example 1 base coat formulation was substituted by 1.62 parts Jagotex MA 2814/MP (terpolymer with an acid number of 125 mg KOH/g and MW about 90K; Ernst Yager GmbH & Co.) and 1.62 parts Joncryl 683 (acrylic polymer with an acid number of 150 mg KOH/g and MW about 10K; S C Johnson & Son, Inc.). The Jagotex terpolymer contains 43.3% styrene, 45% methyl methacrylate, and 11.7% acrylic acid. The base coat was applied and overcoat prepared and applied as described in Example 1. Plates were imaged as described in Example 1. Plates were processed through a Technigraph processor charged with 980 developer (Kodak Polychrome Graphics) equipped with a preheat oven which allowed plates to reach a backside temperature of 125° C. The minimum exposure energy necessary to achieve maximum processed density was about 50 mJ/cm². A second plate prepared as described above was processed through the same Technigraph processor with the preheat oven disabled. No coating was retained following processing.

### Comparative Example 2 and 3

In these examples, the Elvacite 4026 in Example 1 base coat formulation was substituted by either Joncryl 683 (acrylic polymer with an acid number of 150 mg KOH/g and MW about 10,000 g/mol; S C Johnson & Son, Inc.) (Comparative Example 2) or Jagotex MA 2814/MP (terpolymer with an acid number of 125 mg KOH/g and MW about 90K; Ernst Yager GmbH & Co.) (Comparative Example 3). The Jagotex terpolymer contains 43.3% styrene, 45% methyl methacrylate, and 11.7% acrylic acid. The base coat was applied and overcoat prepared and applied as described in Example 1. Plates were imaged as described in Example 1. Plates were processed through a Technigraph processor charged with 980 developer with the preheat oven disabled. No coating was retained following processing for either Comparative Example 2 or Comparative Example

### EXAMPLES 5, 6, and 7

The base coat formulations for Examples 5, 6 and 7 were prepared as described in Example 1 except that N-phenylgylcine (Eastman Kodak) (Example 5), 1H-1,2,4-triazole-3-thiol (Aldrich) (Example 6) or (2-methoxyphenoxy) acetic acid (Aldrich) (Example 7) was used in place of N-phenyliminodiacetic acid. The base coat was applied and overcoat prepared and applied as described in Example 1. Plates were imaged and processed as described in Example 1. The minimum exposure energies necessary to achieve maximum processed density were about 30 mJ/cm^{2 ,} about 30 mJ/cm² and about 40 mJ/cm² for Examples 5, 6 and 7, respectively.

### Comparative Examples 4, 5, and 6

The base coat and overcoat formulations for Comparative Examples 4, 5, and 6 were prepared and coated as described in Comparative Example 1 except that N-phenylgylcine (Eastman Kodak) (Comparative Example 4), 1H-1, 2, 4-triazole-3-thiol (Aldrich) (Comparative Example 5) or (2-methoxyphenoxy) acetic acid (Aldrich) (Comparative Example 6) was used in place of the N-phenyliminodiacetic acid. The plates were imaged as described in Example 1.

The plates were processed through a Technigraph processor charged with 980 developer (Kodak Polychrome Graphics) equipped with a preheat oven which allowed plates to reach a backside temperature of 125° C. The minimum exposure energy necessary to achieve maximum processed density was 120 mJ/cm² (Comparative Example 4), 98 mJ/cm² (Comparative Example 5), and 90 mJ/cm² (Comparative Example 6).

The consequences of altering this component of the initiator system produced much greater effect in Comparative Examples 4, 5, and 6 where the total acid number of the binders was 138 mg KOH/g than in Examples 5, 6, and 7 where the binder had an acid number of zero.

### EXAMPLES 8, 9, 10 and 11

The base coat formulations for Examples 8, 9, 10 and 11 were prepared as described in Example 1 except that in place of 2-(4-methoxyphenyl)-4,6-bis(trichloromethyl)-2-triazine, 2-(4-methylthiophenyl)-4,6-bis(trichlomethyl)-1,3,5-triazine (Lancaster) (Example 8), 2-methoxy-4-(phenylamino)benzenediazonium hexafluorophosphate (Example 9), diphenyl iodonium hexafluorophosphate (prepared according to the method of J. Crivello et al., J. Org. Chem., Vol. 43, 3055 (1978)) (Example 10) or 2,2′-bis(o-chlorophenyl)-4,5,4′, 5′-tetraphenyl biimidazole (Charkit Chemical Corp.) (Example 11) was substituted. The base coat was applied and overcoat prepared and applied as described in Example 1. Plates were imaged and processed as described in Example 1. The minimum exposure energies necessary to achieve maximum processed density were about 26 mJ/cm², about 47 mJ/cm² and about 108 mJ/cm² for Examples 8, 9, and 10, respectively. An image was produced when 2,2′-bis(o-chlorophenyl)-4,5,4′, 5′-tetraphenyl biimidazole was incorporated into the base coat formulation, although the image was not completely resistant to the developer described in Example 1. The estimated minimum exposure energies necessary to achieve maximum processed density was about 100 mJ/cm² for Example 11.

### Comparative Example 7

The base coat formulation for Comparative Example 7 was prepared as described in Comparative Example 1 except that in place of 2-(4-methoxyphenyl)-4,6-bis(trichloromethyl)-2-triazine, 2-methoxy-4-(phenylamino)benzenediazonium hexafluorophosphate was used. The base coat was applied and overcoat prepared and applied as described in Example 1. Plates were imaged as described in Example 1. Plates were processed through a Technigraph processor charged with 980 developer (Kodak Polychrome Graphics) equipped with a preheat oven which allowed plates to reach a backside temperature of 125° C. No image resulted as the entire coating prematurely cured. When this plate was processed with the Technigraph preheat oven disabled the entire coating was also prematurely cured and no image present. This was an unfavorable result as compared to Example 9 with the poly(methyl methacrylate) based polymers which produced acceptable images on the plate.

### EXAMPLE 12

The base coat formulation for Example 12 was prepared as described in Example 1 except that in place of Elvacite 4026, poly(benzyl methacrylate) (acid number 0 mg KOH/mg from Aldrich) was substituted.

The base coat was applied and overcoat prepared and applied as described in Example 1. Plates were imaged and processed as described in Example 1. The minimum exposure energy necessary to achieve maximum processed density was about 22 mJ/cm².

### EXAMPLE 13

The base coat formulation for Example 13 was prepared as described in Example 1 except that the amount of the infrared absorber, 2-[2-[2-thiophenyl-3-[2-( 1, 3-dihydro-1,3,3-trimethyl-2H-indol-2-ylidene)-ethylidene]-1-cyclohexen-1-yl]-ethenyl]-1,3,3-trimethyl-3H-indoliumchloride, was reduced to 0.0042 parts by weight and the 1-methoxy-2-propanol was increased to 55.0658 parts by weight. The base coat was applied and overcoat prepared and applied as described in Example 1. The plates were imaged as described in Example 1. In one case, the plate was directly processed with the developer described in Table 2 without a post-exposure heating step. The minimum exposure energy necessary to achieve maximum processed density was 79 mJ/cm². In another case, the plate was subjected to a post-exposure preheating step. During the post-exposure heating step the plate was passed through a Wisconsin oven set at 268° C. with a conveyor speed of 3 ft/min. This produced a temperature on the backside of the plate of 125° C. The plates were processed with the developer described in Table 2. The minimum exposure energy necessary to achieve maximum processed density in this case was 63 mJ/cm². By eliminating the post-exposure baking step, there is only about a 20% loss in minimum exposure energy necessary to reach maximum density. In Comparative Example 1, the difference between the preheated plates and the non-preheated plates was much greater than 150%. This example also illustrates the efficiency of this invention to effectively absorb enough infrared radiation during imaging to produce a satisfactory image, even with the infrared absorber content decreased nearly 20-fold.

EXAMPLES 14, 15, and 16

The base coat formulations for Examples 14, 15, and 16 were prepared as described in Example 1 with the exception that the following cellulose acetate propionate polymers (from Eastman Chemical Company) were used in place of Elvacite 4026: CAP-540-0.2 (Example 14), CAP-482-0.5 (Example 15), and CAP-482-20 (Example 16). The acid number of these polymers was 0 mg KOH/ g. The base coat was applied and overcoat prepared and applied and the plates were imaged and processed as described in Example 1. The minimum exposure energy necessary to achieve maximum processed density was about 25 mJ/cm² in Example 14, about 35 mJ/cm² in Example 15 and about 37 mJ/cm² in Example 16.

The present invention has been described with particular reference to the preferred embodiments. It should be understood that variations and modifications thereof can be devised by those skilled in the art without departing from the spirit and scope of the present invention. Accordingly, the present invention embraces all such alternatives, modifications and variations that fall within the scope of the appended claims.

What is claimed is:

1. An IR-sensitive composition comprising:
a polymeric binder; and
a free radical polymerizable system consisting of: at least one component selected from unsaturated free radical polymerizable monomers, oligomers which are free radical polymerizable and polymers containing C═C bonds in the backbone and/or in the side chain groups;
and an initiator system comprising: (a) at least one compound capable of absorbing IR radiation; (b) at least one compound capable of producing radicals; and (c) at least one carboxylic acid represented by the formula: 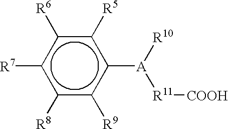
wherein each of R ⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵and R⁶, R⁶ and R⁷, R⁷ and R⁸, or R⁸ and R⁹ together optionally form an aromatic or aliphatic ring;
wherein R¹⁰ is selected from the group consisting of: hydrogen, alkyl, aryl, hydroxyalkyl, carboxyalkyl, acyl, alkoxycarbonyl, alkylsulfonyl and alkylsulfonate; or R¹⁰ and its bond together optionally form an electron pair; or R⁹ and R¹¹ together optionally form a ring;
wherein R¹¹ is an alkylene group of C₁-C₆ carbon atoms; and
wherein R¹⁰ and R¹¹ together optionally form an aliphatic ring;
wherein A is a heteroatom selected from the group consisting of: N, O and S;
with the proviso that the total acid number of said polymeric binder is 70 mg KOH/g or less.

2. The composition of claim 1, wherein said carboxyalkyl groups are represented by the formula:
—C_{y}H_{2y}—COOH
wherein y is an integer from 1 to 6.

3. The composition of claim 1, wherein said compound capable of absorbing IR radiation is selected from the group consisting of: a dye, a pigment and a combination thereof.

4. The composition of claim 1, wherein said compound capable of producing radicals is selected from the group consisting of: an azinium compound, a polyhaloalkyl-substituted compound and a combination thereof.

5. The composition of claim 1, wherein the total acid number of said polymeric binder is 50 mg KOH/g or less.

6. The composition of claim 5, wherein the total acid number of said polymeric binder is 30 mg KOH/g or less.

7. The composition of claim 6, wherein the total acid number of said polymeric binder is 10 mg KOH/g or less.

8. The composition of claim 7, wherein the total acid number of said polymeric binder is 0 mg KOH/g.

9. The composition of claim 1, wherein said polymeric binder is from about 20 wt % to about 80 wt % of the total weight of the composition.

10. The composition of claim 1, wherein said free radical polymerizable system is from about 35 wt % to about 65 wt % of the total weight of the composition.

11. The composition of claim 1, wherein said initiator system is from about 3.5 wt % to about 45 wt % of the total weight of the composition.

12. The composition of claim 1, wherein said binder is selected from the group consisting of: a polymer derived from an acrylic ester, cellulose polymer, and a combination thereof.

13. A printing plate precursor, comprising:
a substrate; and
coated on said substrate an IR-sensitive composition comprising: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system comprising: (a) at least one compound capable of absorbing IR radiation; (b) at least one compound capable of producing radicals; and (c) at least one carboxylic acid represented by the formula: 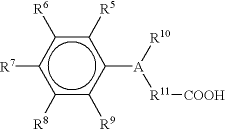
wherein each of R⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵ and R⁶, R⁶ and R⁷, R⁷ and R⁸, or R⁸ and R⁹ together optionally form an aromatic or aliphatic ring; wherein R¹⁰ is selected from the group consisting of: hydrogen, alkyl, aryl, hydroxyalkyl, carboxyalkyl, acyl, alkoxycarbonyl, alkylsulfonyl and alkylsulfonate; or R¹⁰ and its bond together optionally form an electron pair; or R⁹ and R¹¹ together optionally form a ring; wherein R¹¹ is an alkylene group of C₁-C₆ carbon atoms; and wherein R¹⁰ and R¹¹ together optionally form an aliphatic ring; wherein A is a heteroatom selected from the group consisting of: N, O and S; with the proviso that the total acid number of said polymeric binder is 70 mg KOH/g or less.

14. The printing plate precursor of claim 13, further comprising:
an oxygen-impermeable overcoat.

15. A process for preparing a printing plate, comprising:
imagewise exposing a printing plate precursor to IR radiation, said printing plate precursor comprising: a substrate; and coated on said substrate an IR-sensitive composition comprising: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system comprising: (a) at least one compound capable of absorbing IR radiation; (b) at least one compound capable of producing radicals; and (c) at least one carboxylic acid represented by the formula: 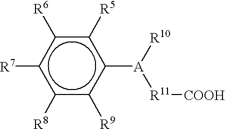
wherein each of R⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵ and R⁶, R⁶ and R⁷, R⁷ and R⁸, or R⁸ and R⁹ together optionally form an aromatic or aliphatic ring; wherein R¹⁰ is selected from the group consisting of: hydrogen, alkyl, aryl, hydroxyalkyl, carboxyalkyl, acyl, alkoxycarbonyl, alkylsulfonyl and alkylsulfonate; or R¹⁰ and its bond together optionally form an electron pair; or R⁹ and R¹¹ together optionally form a ring;
wherein R¹¹ is an alkylene group of C₁-C₆ carbon atoms; and wherein R¹⁰ and R¹¹ together optionally form an aliphatic ring; wherein A is a heteroatom selected from the group consisting of: N, O and S; with the proviso that the total acid number of said polymeric binder is 70 mg KOH/g or less; and thereafter
developing with a developer solution to produce the printing plate.

16. The process of claim 15, further comprising:
heating said exposed precursor before said developing step.

17. The process of claim 15, further comprising:
post development baking or UV-curing.

18. The process of claim 15, wherein said printing plate precursor further comprises: an oxygen-impermeable overcoat.

19. A printing plate prepared by the process of claim 14.

20. A method for producing an image, comprising:
coating an optionally pretreated substrate with an IR-sensitive composition comprising: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system comprising: (a) at least one compound capable of absorbing IR radiation; (b) at least one compound capable of producing radicals; and (c) at least one carboxylic acid represented by the formula: 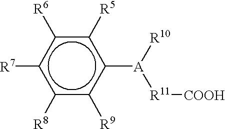
wherein each of R⁵, R⁶, R⁷, R⁸ and R⁹ is independently selected from the group consisting of: hydrogen, alkyl, aryl, halogen, alkoxy, hydroxyalkyl, carboxyalkyl, alkylthio, alkylsulfonyl, sulfonic, alkylsulfonate, dialkylamino, acyl, alkoxycarbonyl, cyano and nitro; wherein R⁵ and R⁶, R⁶ and R⁷, R⁷ and R⁸, or R⁸ and R9 together optionally form an aromatic or aliphatic ring; wherein R¹⁰ is selected from the group consisting of:
hydrogen, alkyl, aryl, hydroxyalkyl, carboxyalkyl, acyl, alkoxycarbonyl, alkylsulfonyl and alkylsulfonate; or R¹⁰ and its bond together optionally form an electron pair; or R⁹ and R¹¹ together optionally form a ring;
wherein R¹¹ is an alkylene group of C₁-C₆ carbon atoms; and wherein R¹⁰ and R¹¹ together optionally form an aliphatic ring; wherein A is a heteroatom selected from the group consisting of: N, O and S; with the proviso that the total acid number of said polymeric binder is 70 mg KOH/g or less to produce a printing plate precursor;
imagewise exposing said printing plate precursor to IR radiation to produce an imagewise exposed printing plate precursor; and thereafter
developing the precursor with an aqueous developer to obtain a printing plate having thereon a printable lithographic image.

21. A printing plate having thereon a printable lithographic image prepared according to the method of claim 20.

22. An IR-sensitive composition comprising:
a polymeric binder; and
a free radical polymerizable system consisting of: at least one component selected from unsaturated free radical polymerizable monomers, oligomers which are free radical polymerizable and polymers containing C═C bonds in the backbone and/or in the side chain groups; and an initiator system comprising: (a) at least one compound capable of absorbing IR radiation; (b) at least one compound capable of producing radicals; and (c) at least one polycarboxylic acid having an aromatic moiety substituted with a heteroatom selected from N, O and S and further having at least two carboxyl groups wherein at least one of said carboxyl groups is bonded to said heteroatom via a methylene group; with the proviso that the total acid number of said polymeric binder is 70 mg KOH/g or less.

23. The composition of claim 22, wherein said compound capable of absorbing IR radiation is selected from the group consisting of: triarylamine dyes, thiazolium dyes, indolium dyes, oxazolium dyes, cyanine dyes, polyaniline dyes, polypyrrole dyes, polythiophene dyes, leuco dyes, phthalocyanine pigments and dyes and a combination thereof.

24. The composition of claim 23, wherein said compound capable of absorbing IR-radiation is a cyanine dye represented by formula (A): 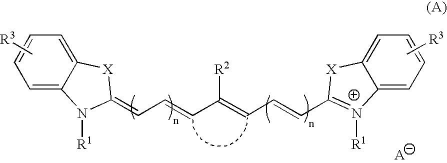
wherein each X is independently selected from the group consisting of: S, O, NR and C(alkyl)₂;
each R¹ is independently selected from the group consisting of: an alkyl, an alkylsulfonate and an alkylammonium group;
R² is selected from the group consisting of: hydrogen, halogen, SR, SO₂R, OR and NR₂;
each R³ is independently selected from the group consisting of: a hydrogen, an alkyl group, COOR, OR, SR, SO₃⁻, NR₂, a halogen, and an optionally substituted benzofused ring;
A⁻ represents an anion;
---represents an optional five- or six-membered carbocyclic ring;
wherein each R is independently selected from the group consisting of: hydrogen, an alkyl and an aryl group; and
wherein each n is an integer independently selected from the group consisting of: 0, 1, 2 and 3.

25. The composition of claim 24, wherein said compound capable of absorbing IR radiation is selected from the group consisting of:
2-[2-[2-phenylsulfonyl-3-[2-(1,3-dihydro-1,3,3-trimethyl-2H-indol-2-ylidene)-ethylidene]-1-cyclohexen-1-yl]-ethenyl]-1,3,3-trimethyl-3H-indoliumchloride;
2-[2-[2-thiophenyl-3-[2-(1,3-dihydro-1,3,3-trimethyl-2H-indol-2-ylidene)-ethylidene]-1-cyclohexen-1-yl]-ethenyl]-1,3,3-trimethyl-3H-indoliumchloride;
2-[2-[2-thiophenyl-3-[2-(1,3-dihydro-1,3,3-trimethyl-2H-indol-2-ylidene)-ethylidene]-1-cyclopenten-1-yl]-ethenyl]-1, 3,3-trimethyl-3H-indoliumtosylate;
2-[2-[2-chloro-3-[2-ethyl-(3H-benzthiazole-2-ylidene)-ethylidene]-1-cyclohexen-1-yl]-ethenyl]-3-ethyl-benzthiazolium-tosylate;
2-[2-[2-chloro-3-[2-(1,3-dihydro-1,3,3-trimethyl-2H-indol-2-ylidene)-ethylidene]-1-cyclohexen-1-yl]-ethenyl]-1,3,3-trimethyl-3H-indolium tosylate; and a combination thereof.

26. The composition of claim 22, wherein said compound capable of producing radicals is selected from the group consisting of: polyhaloalkyl-substituted compounds, azinium compounds and a combination thereof.

27. The composition of claim 26, wherein said compound capable of producing radicals is selected from the group consisting of:
N-methoxy-4-phenyl-pyridinium tetrafluoroborate tribromomethylphenyisulfone;
1,2,3,4-tetrabromo-n-butane;
2-(4-methoxyphenyl)-4,6-bis(trichloromethyl)-s-triazine-2-(4-chlorophenyl)-4,6-bis(trichloromethyl)-s-triazine;
2-phenyl-4,6-bis(trich loromethyl)-s-triazine;
2,4,6-tri-(trichloromethyl)-s-triazine;
2,4,6-tri-(tribromomethyl)-s-triazine;
2-hydroxytetradecyloxyphenyl phenyliodonium hexafluoroantimonate;
2-methoxy-4-phenylaminobenzenediazonium hexafluorophosphate and a combination thereof.

28. The composition of claim 22, wherein said polycarboxylic acid is selected from the group consisting of:
a compound represented by the formula (B): 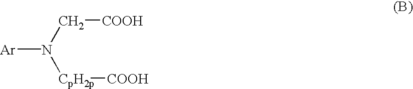
wherein Ar is selected from the group consisting of: an unsubstituted aryl, a mono-substituted aryl and poly-substituted aryl group; and p is an integer from 1 to 5;
a compound represented by the formula (C): 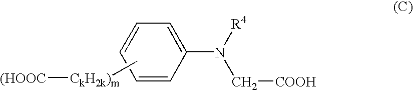
wherein R⁴ is selected from the group consisting of: hydrogen and a C₁-C₆ alkyl group; and wherein each of k and m is independently an integer from 1 to 5; and
a combination of compounds represented by formula (B) and (C).

29. The composition of claim 26, wherein said polycarboxylic acid is N-phenyliminodiacetic acid.

30. The composition of claim 22, further comprising one or more dyes for increasing the contrast of the image.

31. The composition of claim 22, wherein the total acid number of said polymeric binder is 50 mg KOH/g or less.

32. The composition of claim 31, wherein the total acid number of said polymeric binder is 30 mg KOH/g or less.

33. The composition of claim 32, wherein the total acid number of said polymeric binder is 10 mg KOH/g or less.

34. The composition of claim 33, wherein the total acid number of said polymeric binder is 0 mg KOH/g.

35. The composition of claim 22, wherein said polymeric binder is from about 20 wt % to about 80 wt % of the total weight of the composition.

36. The composition of claim 22, wherein said free radical polymerizable system is from about 35 wt % to about 65 wt % of the total weight of the composition.

37. The composition of claim 22, wherein said initiator system is from about 3.5 wt % to about 45 wt % of the total weight of the composition.

38. A printing plate precursor, comprising:
a substrate; and
coated on said substrate an IR-sensitive composition comprising: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system comprising: (a) at least one compound capable of absorbing IR radiation; (b) at least one compound capable of producing radicals; and (c) at least one polycarboxylic acid having an aromatic moiety substituted with a heteroatom selected from N, O and S and further having at least two carboxyl groups wherein at least one of said carboxyl groups is bonded to said heteroatom via a methylene group; with the proviso that the total acid number of said polymeric binder is 70 mg KOH/g or less.

39. The printing plate precursor of claim 38, further comprising:
an oxygen-impermeable overcoat.

40. A process for preparing a printing plate, comprising:
imagewise exposing a printing plate precursor to IR radiation, said printing plate precursor comprising: a substrate; and coated on said substrate an IR-sensitive composition comprising: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system comprising: (a) at least one compound capable of absorbing IR radiation; (b) at least one compound capable of producing radicals; and (c) at least one polycarboxylic acid having an aromatic moiety substituted with a heteroatom selected from N, O and S and further having at least two carboxyl groups wherein at least one of said carboxyl groups is bonded to said heteroatom via a methylene group; with the proviso that the total acid number of said polymeric binder is 70 mg KOH/g or less; and thereafter
developing with a developer solution to produce the printing plate.

41. The process of claim 40, further comprising:
heating said exposed precursor before said developing step.

42. The process of claim 40, further comprising:
post development baking or UV-curing.

43. The process of claim 40, wherein said printing plate precursor further comprises:
an oxygen-impermeable overcoat.

44. A printing plate prepared by the process of claim 40.

45. A method for producing an image, comprising:
coating an optionally pretreated substrate with an IR-sensitive composition comprising: a polymeric binder; and a free radical polymerizable system consisting of: at least one component selected from unsaturated free radical polymerizable monomers, oligomers which are free radical polymerizable and polymers containing C═C bonds in the backbone and/or in the side chain groups; and an initiator system comprising: (a) at least one compound capable of absorbing IR radiation; (b) at least one compound capable of producing radicals; and (c) at least one polycarboxylic acid having an aromatic moiety substituted with a heteroatom selected from N, O and S and further having at least two carboxyl groups wherein at least one of said carboxyl groups is bonded to said heteroatom via a methylene group; with the proviso that the total acid number of said polymeric binder is 70 mg KOH/g or less to produce a printing plate precursor;
imagewise exposing said printing plate precursor to IR radiation to produce an imagewise exposed printing plate precursor; and thereafter
developing the precursor with an aqueous developer to obtain a printing plate having thereon a printable lithographic image.
